(19) United States
(12) Patent Application Publication
(10) Pub. No.: US 2010/0060507 A1
(43) Pub. Date: Mar. 11, 2010

(54) ELECTRONIC WARFARE RECEIVER HAVING DIGITAL ANTENNA

(75) Inventors: Ryan D. Raba, Endwell, NY (US); James A. Johnson, Owego, NY (US)

Correspondence Address: Lockheed Martin Corporation;c/o WOLF, GREENFIELD & SACKS, P.C., 600 ATLANTIC AVENUE, BOSTON, MA, 02210-2206, US

(73) Assignee: Lockheed Martin Corporation, Bethesda, MD (US)

(21) Appl. No.: 12/206,989

(22) Filed: Sep. 9, 2008

(51) Int. Cl. G01S 7/42; G01R 29/08

(52) U.S. Cl. 342/13; 343/703

(57) ABSTRACT

Methods and apparatus for detecting and measuring electromagnetic radiation using a digital antenna are provided. Receiver apparatus includes a digital antenna having an array of pixels, each pixel configured to produce a voltage that represents received photons at a photon frequency of the pixel, and a processing unit configured to sample the voltage of each pixel at multiple sampling times to acquire a set of voltage samples and to process the sets of voltage samples and corresponding sampling times to provide information on one or more detected signals represented by the received photons.

### FIELD OF THE INVENTION

This invention relates to passive electronic warfare receivers and, more particularly, to methods and apparatus for detecting and measuring electromagnetic radiation using a digital antenna.

### BACKGROUND OF THE INVENTION

Current electronic warfare receivers use the same basic analog technology pioneered nearly 100 years ago. This analog technology detects radio and microwave band photons by using an antenna and shielded cabling. The received photons are focused by the antenna to maximize the induced voltage in the shielded cable. The varying induced voltage is then filtered and mixed to achieve an appropriate intermediate frequency and bandwidth for measurement.

Current antennas, connecting cables and analog receiver hardware are both expensive and heavy. Most antenna and receiver systems cost in excess of $500,000 per unit, are in excess of 100 pounds in weight and require over 500 watts of power. This limits the platforms on which electronic warfare receivers can be utilized and the customer base willing to pay for such systems. Additionally, the measurement techniques utilized can process only one narrow frequency range at a time. If a large detection frequency range is required, the receiver is sequentially tuned through each frequency bandwidth, with enough time allowed at each interval to detect the desired signals. This lengthens the amount of time required to scan a large frequency range and to measure the signals present. Modern military radar uses stealthy, low probability-of-intercept signals that are radiating for short periods of time and are difficult to detect with limited bandwidth receivers. Additionally, problems arise when a signal of varying frequency moves outside the bandwidth currently being scanned. Techniques must be employed to reconstruct a signal detected at different times in different frequency bands. These techniques are not feasible for stealthy signals that may not reappear at regular intervals.

Accordingly, there is a need for improved electronic warfare receiver systems.

### SUMMARY OF THE INVENTION

According to a first aspect of the invention, receiver apparatus comprises a digital antenna comprising a semiconductor device including a plurality of pixels, each pixel configured to produce a voltage that represents received photons at a photon frequency of the pixel, a measurement unit configured to sample the voltage of each pixel at multiple sampling times to acquire a set of voltage samples for each pixel and to record the set of voltage samples and corresponding sampling times, and a receiver processor configured to process the sets of voltage samples and corresponding sampling times to provide information on one or more detected signals represented by the received photons.

According to a second aspect of the invention, a method for receiving electromagnetic radiation comprises (a) detecting radiation with a digital antenna comprising a semiconductor device including a plurality of pixels, each pixel configured to produce a voltage that represents received photons at a photon frequency of the pixel, (b) sampling the voltage of each pixel of the digital antenna, (c) recording the voltage sample and corresponding sampling time for each pixel, (d) resetting each pixel following sampling, (e) repeating acts (b)-(d) to acquire a set voltage samples for each of the pixels in the digital antenna, and (f) processing the sets of voltage samples and corresponding sampling times to provide information on one or more detected signals represented by the received photons.

According to a third aspect of the invention, receiver apparatus comprises a digital antenna comprising an array of pixels, each pixel configured to produce a voltage that represents received photons at a photon frequency of the pixel, and a processing unit configured to sample the voltage of each pixel at multiple sampling times to acquire a set of voltage samples and to process the sets of voltage samples and corresponding sampling times to provide information on one or more detected signals represented by the received photons.

### BRIEF DESCRIPTION OF THE DRAWINGS

For a better understanding of the present invention, reference is made to the accompanying drawings, which are incorporated herein by reference and in which:

FIG. 1 is schematic block diagram of receiver apparatus in accordance with an embodiment of the invention;

FIG. 2 is a schematic representation of a digital antenna in accordance with an embodiment of the invention;

FIG. 3 is a schematic block diagram that illustrates sampling of pixels in the digital antenna in accordance with an embodiment of the invention;

FIG. 4 is a timing diagram that illustrates sampling of pixels in the digital antenna in accordance with an embodiment of the invention;

FIG. 5 is a schematic block diagram of receiver apparatus in accordance with another embodiment of the invention; and

FIG. 6 is a schematic block diagram of receiver apparatus in accordance with a further embodiment of the invention.

### DETAILED DESCRIPTION

The present invention provides novel methods and apparatus for detecting and measuring electromagnetic radiation. The apparatus includes a digital antenna to detect electromagnetic radiation and a processing unit to process outputs of the digital antenna. The detected electromagnetic radiation may represent one or more signals transmitted by one or more emitters. Rather than relying on the induced voltage caused by an electric field, individual photons are collected by the digital antenna and converted directly into a binary value. The binary photon count represents the electromagnetic wave measurement. The apparatus is particularly useful in passive electronic warfare applications but is not limited to such applications.

In some embodiments, the digital antenna includes a semiconductor device configured as an array of pixels. The semiconductor device includes a doped semiconductor surface followed by a series of voltage potential well pixels. The semiconductor device is doped to lower the energy gap of the valence band below the threshold of radio frequency photons. When a radio frequency photon strikes the semiconductor device, an electron is excited into the conduction band and is trapped by a potential well pixel. Each trapped electron lowers the voltage of the pixel. The number of electrons contained in a pixel at any given time can be determined by measuring the voltage of the pixel.

The potential well pixels in the digital antenna are precisely set to trap only electrons of a given energy. Each pixel is responsible for capturing the excited electrons from a specific photon frequency. The frequency bandwidth and resolution of the digital antenna depend on both the total number of pixels in the array and the energy tolerance of each pixel.

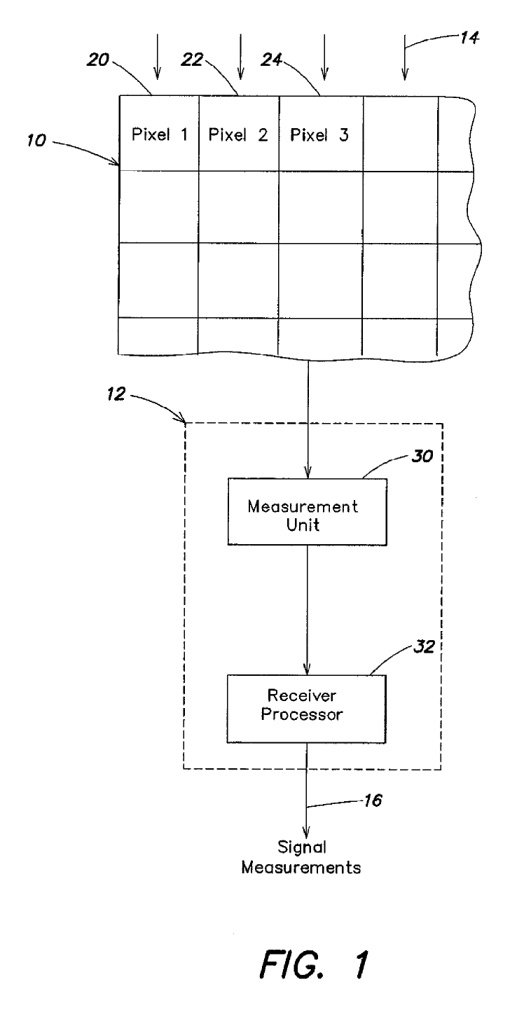

A block diagram of receiver apparatus in accordance with an embodiment of the invention is shown in FIG. 1. A digital antenna 10 is coupled to a processing unit 12. The digital antenna 10 detects electromagnetic radiation 14 and provides samples of detected signals to processing unit 12. Processing unit 12 processes the detected signal samples and outputs signal measurements 16.

Digital antenna 10 may include an array of pixels 20, 22, 24, etc. on a semiconductor device as described below. Each pixel 20, 22, 24, etc. in digital antenna 10 is configured to detect photons at a specific photon frequency. In practice, each pixel detects photons over a limited frequency range. The photon frequencies of the pixels in the pixel array are selected to cover a desired frequency range. The digital antenna 10 may be configured to detect received photons over one or more frequency ranges or at specified photon frequencies. The number of pixels in digital antenna 10 depends on the number of photon frequencies of interest. The array of pixels may be configured as an array of rows and columns of pixels, but is not limited to this configuration. The digital antenna 10 may include any number of pixels.

In the embodiment of FIG. 1, processing unit 12 includes a measurement unit 30 and a receiver processor 32. Measurement unit 30 is connected to each of the pixels 20, 22, 24, etc. of digital antenna 10 and samples each of the pixels of digital antenna 10 at a sampling frequency. Measurement unit 30 also resets each pixel after each sample is taken. Sampling information, including the samples and corresponding sampling times, are stored in a memory, either in measurement unit 30 or in receiver processor 32. Receiver processor 32 processes the sampling information acquired from digital antenna 10 to determine detected signal parameters, such as signal amplitudes, signal frequencies, pulse widths, pulse repetition rates, emitter direction, and the like. It will be understood that processing unit 12 may have different architectures within the scope of the present invention. Measurement unit 30 may sample all of the pixels in digital antenna 10 or may sample one or more subsets of the pixels in digital antenna 10.

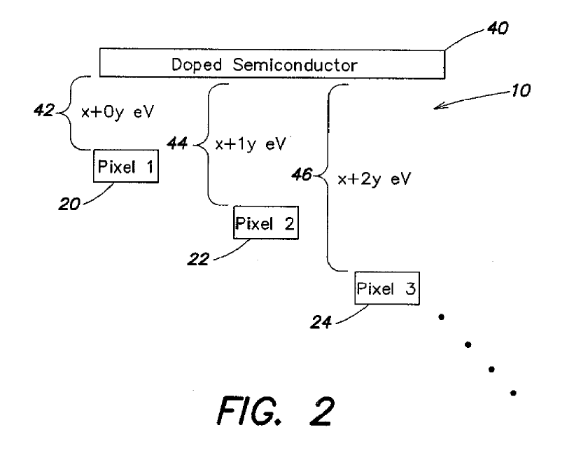

Each pixel is capable of trapping only those electrons with a specific energy range above the bandgap. This limits the pixels to known frequency ranges. By staggering the pixel bandgaps at fixed intervals, a frequency range for the digital antenna is established. FIG. 2 is a pictorial diagram that illustrates the bandgaps of pixels in digital antenna 10. Digital antenna 10 includes a doped semiconductor material 40 with pixels 20, 22, 24 characterized by bandgaps 42, 44, 46, respectively. The bandgaps 42, 44, 46 are different, so that each pixel detects photons at a different photon frequency. The bandgap of a pixel may be represented by x+ny electron volts, where variable x represents the minimum energy of the bandgap, variable y represents an energy increment and variable n is selected to establish the bandgap of each pixel in the array of pixels. The value of variable n may be different for different pixels. The frequency resolution of the digital antenna is determined by variable y, while the frequency range is determined by the variable x, variable y and the total number of pixels. Additional information regarding pixels of this type is given by way of example only in U.S. Patent Publication No. 2007/0075224, published Apr. 5, 2007 by Jones et al., and U.S. Pat. No. 5,325,129, issued Jun. 28, 1994 to Henry et al., which are hereby incorporated by reference.

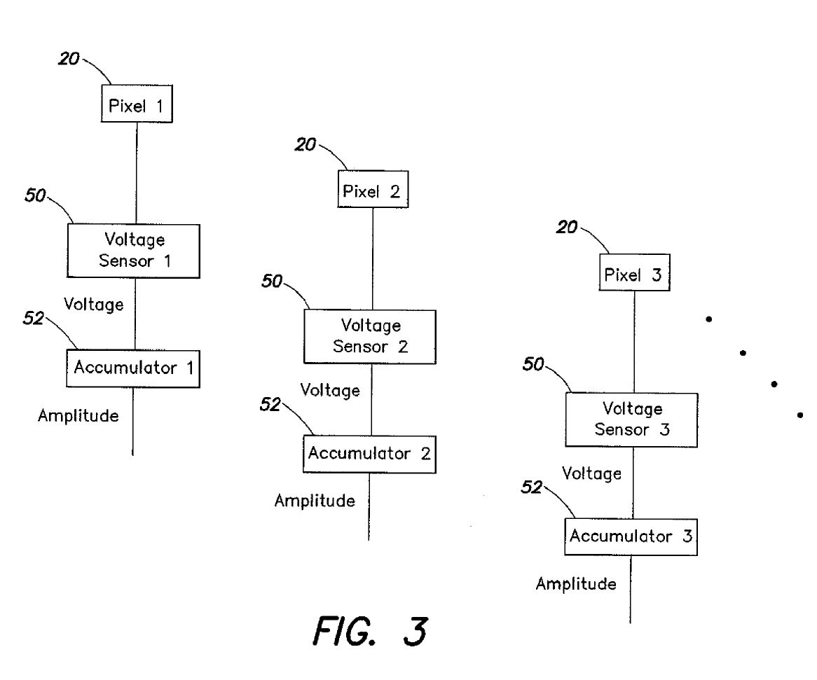

The digital antenna pixels are preset to an arbitrary voltage. Each trapped electron changes the voltage of the pixel by a fixed amount. A high speed voltage sensor 50 and an accumulator 52, attached to each pixel, continuously read out and reset the voltage. The accumulator 52 “counts” the number of electrons in its pixel by subtracting the reading of voltage sensor 50 from the preset pixel voltage and dividing by the electron potential. The resulting count of the number of electrons in each pixel directly yields the number of photons received at the corresponding photon frequency of the pixel. Following each sample, the pixel voltage is reset. After a specified interval, the pixel is sampled again and the pixel voltage is again reset. This cycle continues indefinitely during the operation of the digital antenna. The accumulator 52 outputs the amplitude of each pixel by dividing the number of detected photons by the sample period, as shown in FIG. 3.

The sampling frequency is based on the minimum pulse width measurement desired. For example, a digital antenna designed to detect a radar with a 500 nanosecond pulse width accuracy must read out each pixel at a rate of at least 2 MHz.

The amplitude outputs of each accumulator 52 are supplied to receiver processor 32 which performs the remainder of the signal measurement functions. The receiver processor 32 takes the set of all pixel amplitudes at a given time and subtracts a calibrated noise value from each pixel to determine which pixels contain amplitudes from photons of meaningful signals. The frequencies of the detected signals correspond to the photon frequencies of the detecting pixels. The number of consecutive data sets that contain the same signal are tracked to determine the pulse width of the signal. New pulse measurements are correlated to previous pulse measurements to determine the pulse repetition rate.

The angle of arrival of a detected signal can be any value within the field of view of the digital antenna. The digital antenna detects electromagnetic radiation directly incident on the semiconductor surface. Thus, the field of view can be tightly controlled by limiting the exposure of the semiconductor device. The receiver processor can measure the angle of arrival of a given signal by acquiring multiple channels of input from multiple digital antennas positioned in non-overlapping directions and noting the orientation of the antenna that detects a signal.

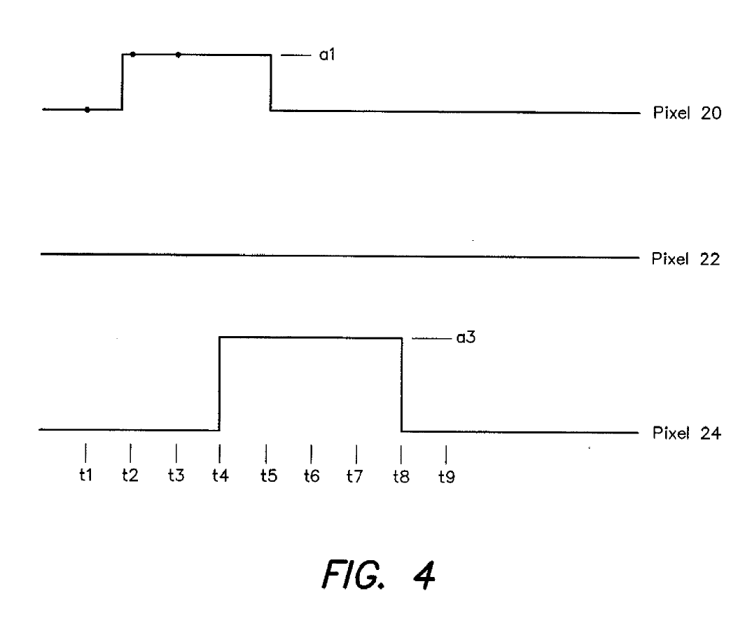

A timing diagram that illustrates an example of the outputs of pixels 20, 22 and 24 is shown in FIG. 4. The outputs of pixels 20, 22 and 24 are sampled at times t1, t2, t3, etc. The pixels of the digital antenna can be sampled simultaneously and are reset following each sample, Sampling is characterized by sampling times, such as times t1, t2, t3 in FIG. 4, which may be considered timestamps. Samples and corresponding sampling times are used by receiver processor 32 to reconstruct a detected signal. Sampling is also characterized by a sampling frequency, which is the rate of sampling. The sampling frequency is selected to insure detection of the minimum expected pulse width. Sampling is further characterized by a sample width, which is the time interval to acquire each individual sample.

Referring again to FIG. 4, for pixel 20, a signal amplitude of zero is recorded at sampling time t1, a signal amplitude a1 is recorded at sampling time t2, a signal amplitude a1 is recorded at sampling time t3, etc. The pulse width corresponds to the number of consecutive sampling times during which a non-zero signal amplitude is present. In the example of FIG. 4, a pulse having an amplitude a1 and a pulse width of t5−t2 is recorded at the photon frequency of pixel 20, no signal is recorded at the photon frequency of pixel 22, and a signal having an amplitude a3 and a pulse width of t8−t4 is recorded at the photon frequency of pixel 24. The pulses in pixels 20 and 24 have different timing characteristics. It may be observed that the digital antenna simultaneously detects signals in different pixels corresponding to different photon frequencies.

Once signal measurements have been produced by the receiver processor, known electronic warfare software algorithms can be applied to determine the identification and location of the detected emitters.

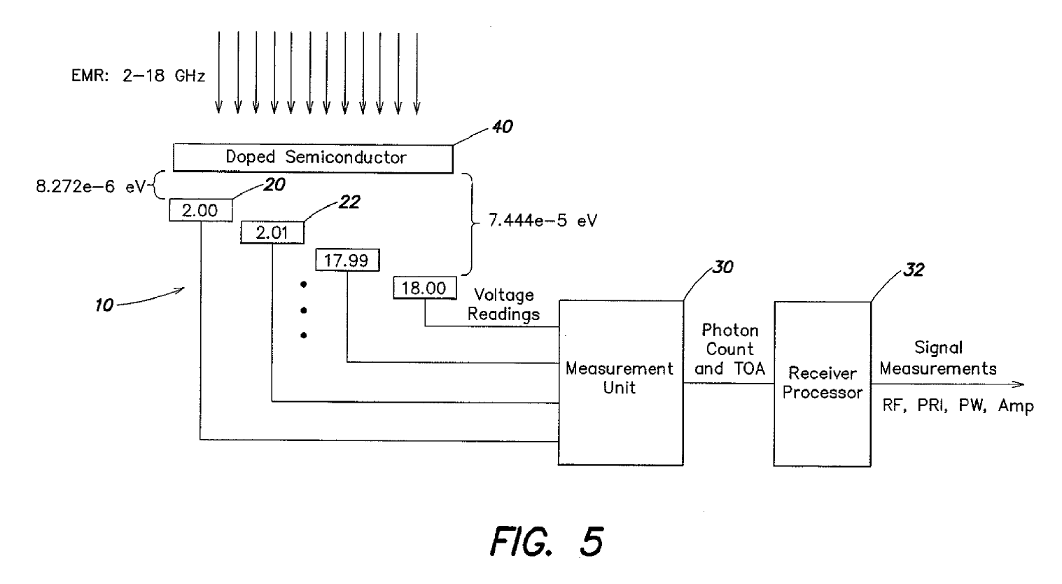

An example of a digital antenna design in accordance with an embodiment of the invention is shown in FIG. 5. The digital antenna 10 is configured for a frequency range of 2 to 18 GHz with a frequency accuracy of 10 MHz. The digital antenna has 1600 pixels, each of which covers a frequency band of 10 MHz. Each pixel has a bandgap which allows radio frequency photons to excite valence band electrons into the conductive band. Each excited electron is trapped in the pixel and lowers the voltage of that pixel. The digital antenna thus has pixels at photon frequencies of 2.00 GHz, 2.01 GHz, 2.02 GHz, . . . 17.99 GHz and 18.00 GHz.

The measurement unit 30 acquires 1600 samples, one for each pixel, at each sampling time by measuring the voltages of the potential wells. The potential well voltage is reset after each sample is taken. The parameters of the detected signals are determined by receiver processor 32 as described above.

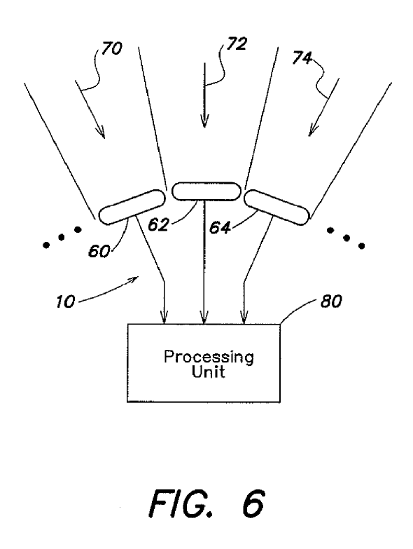

An example of receiver apparatus in accordance with a further embodiment of the invention is shown in FIG. 6. The receiver apparatus includes digital antenna 10 having antenna segments 60, 62, 64, etc. oriented to receive electromagnetic radiation from directions 70, 72, 74, etc., respectively. Each antenna segment 60, 62, 64, etc. may be a semiconductor device having an array of pixels as described above. The outputs of the antenna segments are connected to a processing unit 80. The processing unit 80 determines the direction of a detected signal based on the orientation of the antenna segment that detected the signal. It will be understood that the receiver apparatus can have any number of antenna segments and segment orientations.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. Receiver apparatus comprising:
a digital antenna comprising a semiconductor device including a plurality of pixels, each pixel configured to produce a voltage that represents received photons at a photon frequency of the pixel;
a measurement unit configured to sample the voltage of each pixel at multiple sampling times to acquire a set of voltage samples for each pixel and to record the set of voltage samples and corresponding sampling times; and
a receiver processor configured to process the sets of voltage samples and corresponding sampling times to provide information on one or more detected signals represented by the received photons.

2. Receiver apparatus as defined in claim 1 wherein the measurement unit is configured to reset each pixel following sampling.

3. Receiver apparatus as defined in claim 1, wherein each pixel has a potential well which defines an energy gap that corresponds to the photon frequency of the pixel.

4. Receiver apparatus as defined in claim 1, wherein the pixels of the digital antenna are configured to detect received photons over a range of frequencies.

5. Receiver apparatus as defined in claim 1, wherein a direction of the received photons is based on an orientation of the digital antenna.

6. Receiver apparatus as defined in claim 1, wherein an amplitude of a detected signal is based on values of the voltage samples.

7. Receiver apparatus as defined in claim 1, wherein a pulse width and a pulse repetition frequency of a detected signal are based on analysis of the set of voltage samples and corresponding sampling times.

8. Receiver apparatus as defined in claim 1, wherein a frequency of a detected signal corresponds to a photon frequency of the pixel in which the detected signal is received.

9. Receiver apparatus as defined in claim 1, wherein the digital antenna includes two or more antenna segments having different orientations and wherein a direction of a detected signal is based on the antenna segment in which the detected signal is received.

10. Receiver apparatus as defined in claim 1, wherein the measurement unit is configured to sample the plurality of pixels concurrently.

11. A method for receiving electromagnetic radiation, comprising:
(a) detecting radiation with a digital antenna comprising a semiconductor device including a plurality of pixels, each pixel configured to produce a voltage that represents received photons at a photon frequency of the pixel;
(b) sampling the voltage of each pixel of the digital antenna;
(c) recording the voltage sample and a corresponding sampling time for each pixel;
(d) resetting each pixel following sampling;
(e) repeating acts (b)-(d) to acquire a set of voltage samples for each of the pixels in the digital antenna; and
(f) processing the sets of voltage samples and corresponding sampling times to provide information on one or more detected signals represented by the received photons.

12. A method as defined in claim 11, wherein the voltages of the pixels are sampled concurrently.

13. A method as defined in claim 11, wherein at least one set of voltage samples and corresponding sampling times is processed to determine a direction of a detected signal.

14. A method as defined in claim 11, wherein at least one set of voltage samples and corresponding sampling times is processed to determine a pulse width and a pulse repetition frequency of a detected signal.

15. Receiver apparatus comprising:
a digital antenna comprising an array of pixels, each pixel configured to produce a voltage that represents received photons at a photon frequency of the pixel; and
a processing unit configured to sample the voltage of each pixel at multiple sampling times to acquire a set of voltage samples and to process the sets of voltage samples and corresponding sampling times to provide information on one or more detected signals represented by the received photons.

16. Receiver apparatus as defined in claim 15, wherein the processing unit is configured to reset each pixel of the digital antenna following sampling.

17. Receiver apparatus as defined in claim 15, wherein the pixels of the digital antenna are configured to detect received photons at a plurality of photon frequencies.

18. Receiver apparatus as defined in claim 15, wherein the processing unit comprises a measurement unit configured to sample the voltage of each pixel at multiple sampling times and a receiver processor configured to process the sets of voltage samples and corresponding sampling times.

19. Receiver apparatus as defined in claim 18, wherein the measurement unit is configured to sample the pixels in the array of pixels concurrently.

20. Receiver apparatus as defined in claim 15, wherein the digital antenna includes two or more antenna segments having different orientations and wherein a direction of a detected signal is based on the antenna segment in which the detected signal is received.
